(19) United States
(12) Patent Application Publication
(10) Pub. No.: US 2018/0047595 A1
(43) Pub. Date: Feb. 15, 2018

(54) PLASMA PROCESSING DEVICE AND PLASMA PROCESSING METHOD USING SAME

(71) Applicant: Hitachi High-Technologies Corporation, Minato-ku, Tokyo (JP)

(72) Inventors: Naoyuki KOFUJI, Tokyo (JP); Masahito MORI, Tokyo (JP); Toshiaki NISHIDA, Tokyo (JP); Ryoji HAMASAKI, Tokyo (JP)

(21) Appl. No.: 15/558,005

(22) PCT Filed: Apr. 27, 2016
(86) PCT No.: PCT/JP2016/063129

§ 371 Date: Sep. 13, 2017

(30) Foreign Application Priority Data
May 22, 2015 (JP) 2015-104115

(51) Int. Cl. H01L 21/67; H01L 21/311; H01J 37/32; H01L 27/115

(52) U.S. Cl. CPC H01L 21/67069; H01L 27/115; H01L 21/31116; H01J 37/32192; H01J 37/32715; H01J 37/32651; H01J 37/32678; H01L 27/11578

(57) ABSTRACT

Provided is a plasma processing apparatus capable of implementing both a radical irradiation step and an ion irradiation step using a single apparatus and controlling the ion irradiation energy from several tens eV to several KeV.

The plasma processing apparatus includes a mechanism (125, 126, 131, 132) for generating inductively coupled plasma, a perforated plate 116 for partitioning the vacuum processing chamber into upper and lower areas 106-1 and 106-2 and shielding ions, and a switch 133 for changing over between the upper and lower areas 106-1 and 106-2 as a plasma generation area.

### TECHNICAL FIELD

The present invention relates to a plasma processing apparatus and a plasma processing method using same.

### BACKGROUND ART

Out of dry-etching apparatuses, a dry-etching apparatus having a function of irradiating both ions and radicals and a function of irradiating only radicals by shielding ions is disclosed, for example, in PTL 1 (Japanese Patent Application Laid-Open No. 2015-50362). In the apparatus (ICP+CCP) disclosed in PTL 1, inductively coupled plasma can be generated by supplying radio frequency power to a helical coil.

It is possible to shield ions and irradiate only radicals by inserting a grounded perforated plate formed of metal between the inductively coupled plasma and a sample. In addition, in this apparatus, by applying radio frequency power to the sample, capacitively coupled plasma can be generated between the metal perforated plate and the sample. By adjusting a ratio between the power supplied to the helical coil and the power supplied to the sample, it is possible to adjust a ratio between radicals and ions.

In addition, in a dry-etching apparatus disclosed in PTL 2 (Japanese Patent Application Laid-Open No. 62-14429), plasma (ECR plasma) can be generated using a magnetic field generated by a solenoidal coil and an electron cyclotron resonance (ECR) phenomenon of a microwave having a frequency of 2.45 GHz. Furthermore, a DC bias voltage is generated by applying radio frequency power to a sample, and ions can be irradiated onto a wafer by accelerating the ions using the DC bias voltage.

In addition, in a neutral beam etching apparatus discussed in PTL 3 (Japanese Patent Application Laid-Open No. 4-180621), ECR plasma can be generated in a similar way to that of PTL 2. Furthermore, by inserting a metal perforated plate while applying a voltage between a plasma generating portion and a sample, it is possible to shield ions and irradiate only neutral particles such as radicals, which are not electrically charged, onto the sample.

In a dry-etching apparatus using microwave plasma discussed in PTL 4 (Japanese Patent Application Laid-Open No. 5-234947), plasma can be generated in the vicinity of a quartz window using power of the supplied microwave. Furthermore, by inserting a perforated plate between this plasma and a sample, it is possible to shield ions and supply radicals.

### CITATION LIST

### Patent Literature

PTL 1: Japanese Patent Application Laid-Open No. 2015-50362

PTL 2: Japanese Patent Application Laid-Open No. 62-14429

PTL 3: Japanese Patent Application Laid-Open No. 4-180621

PTL 4: Japanese Patent Application Laid-Open No. 5-234947

### SUMMARY OF INVENTION

### Technical Problem

In recent years, as semiconductor device fabrication becomes sophisticated, the dry-etching apparatus is required to have both a function of performing fabrication by irradiating both ions and radicals and a function of performing fabrication by irradiating only radicals. For example, in atomic layer etching in which an etching depth is controlled with high accuracy, a method of controlling an etching depth by alternately repeating a first step in which only radicals are irradiated onto a sample and a second step in which ions are irradiated onto the sample has been studied. In this fabrication, radicals are adsorbed on a surface of the sample in the first step, and the radicals adsorbed on the surface of the sample are activated by irradiating ions of a noble gas in the second step to generate an etching reaction, so that the etching depth is controlled with high accuracy.

In a case where this atomic layer etching process is performed using a method known in the art, it is necessary to treat a sample by alternately moving it under a vacuum conveyance environment between (1) an apparatus capable of irradiating only radicals onto the sample as described in PTL 3, PTL 4, and the like and (2) an apparatus capable of accelerating ions of plasma and irradiating them onto the sample as described in PTL 2 and the like. Therefore, in such a method of the atomic layer etching, a throughput is significantly degraded disadvantageously. For this reason, it is preferable to perform both a first step in which only radicals are irradiated onto the sample using a single dry-etching apparatus and a second step in which ions are irradiated onto the sample.

For example, in isotropic silicon fabrication, it is necessary to remove natural oxide on a silicon surface by irradiating both ions and radicals and then perform isotropic etching of silicon by irradiating only radicals. In this fabrication, the time necessary to remove natural oxide is merely several seconds which is short. Therefore, if different apparatuses are used in removal of natural oxide and in isotropic etching of silicon, the throughput is significantly degraded. For this reason, it is preferable that a single dry-etching apparatus be used in both the removal of natural oxide by irradiating both ions and radicals and the isotropic etching of silicon by irradiating radicals.

In addition, for example, in a medium-sized fabrication laboratory (fab) producing a small quantity and a wide variety of products, a single etching apparatus is used to perform a plurality of processes. Therefore, if an apparatus has both the function of anisotropic etching by irradiating both ions and radicals and the function of isotropic etching by irradiating only radicals, it is possible to remarkably reduce the equipment cost.

As described above, the dry-etching apparatus used in semiconductor device fabrication is required to have both the function of fabrication by irradiating both ions and radicals and the function of fabrication by irradiating only radicals.

The apparatus of PTL 1 has been considered as a solution for this requirement. That is, in irradiation of radicals in the first step, inductively coupled plasma is generated by supplying radio frequency power to a helical coil. Meanwhile, the radio frequency voltage is not applied to the sample. As a result, only radicals are supplied to the sample from the inductively coupled plasma. In addition, in irradiation of ions of the second step, capacitively coupled plasma is generated between a metal perforated plate and a sample by applying a radio frequency voltage to the sample to irradiate ions onto the sample. However, in this method, in order to generate capacitively coupled plasma and irradiate ions onto the sample, it is necessary to apply a large radio frequency voltage having an order of several KeV to the sample. For this reason, it was found that it is difficult to apply this method to high selectivity fabrication requiring low energy ion irradiation of several tens electron volts (eV).

In addition, it was found that the usable pressure range is as high as several hundreds Pa, so that this method is not suitable for micro-fabrication requiring low-pressure processing.

In view of the aforementioned problems, an object of the present invention is to provide a plasma processing apparatus and a plasma processing method using same, capable of implementing both a radical irradiation step and an ion irradiation step using a single apparatus and controlling the ion irradiation energy from several tens eV to several KeV.

### Solution to Problem

In order to achieve the aforementioned object, there is provided a plasma processing apparatus including: a processing chamber configured to perform plasma processing for a sample; a plasma generation mechanism configured to generate plasma in the processing chamber; a sample stage where the sample is placed; a shielding plate arranged over the sample stage to shield incidence of ions generated from the plasma into the sample stage; and a controller configured to control plasma processing by changing over between a first period for generating plasma over the shielding plate and a second period for generating plasma under the shielding plate.

In addition, there is provided a plasma processing apparatus including: a processing chamber configured to perform plasma processing for a sample; a radio frequency power source configured to supply radio frequency power for generating plasma in the processing chamber; a sample stage where the sample is placed; a shielding plate arranged over the sample stage to shield incidence of ions generated from the plasma into the sample stage; and a controller configured to selectively perform one of controls for generating plasma over the shielding plate and the other control for generating plasma under the shielding plate.

In addition, there is provided a plasma processing method for performing plasma processing for a sample using a plasma processing apparatus including: a processing chamber configured to perform plasma processing for a sample; a plasma generation mechanism configured to generate plasma in the processing chamber; a sample stage where the sample is placed; and a shielding plate arranged over the sample stage to shield incidence of ions generated from the plasma into the sample stage, the plasma processing method including a first process for performing plasma processing for the sample using plasma generated under the shielding plate and a second process for performing plasma processing for the sample undergoing the first process using plasma generated over the shielding plate after the first process.

In addition, there is provided a plasma processing method for removing a portion of a film buried in a pattern formed on a side wall of a hole or a trench other than the pattern by performing plasma etching, wherein the film is removed perpendicularly to a depth direction of the hole or the trench after the film on the bottom surface of the hole or the trench is removed.

### Advantageous Effects of Invention

According to the present invention, it is possible to provide a plasma processing apparatus and a plasma processing method using same, capable of implementing both a radical irradiation step and an ion irradiation step using a single apparatus and controlling the ion irradiation energy from several tens eV to several KeV.

### BRIEF DESCRIPTION OF DRAWINGS

FIG. 1 is a schematic cross-sectional view illustrating a whole configuration of a plasma processing apparatus according to a first embodiment of the invention.

FIG. 2 is a schematic cross-sectional view illustrating a whole configuration of a plasma processing apparatus according to a second embodiment of the invention.

FIG. 3 is diagram illustrating a cross-sectional shape of a sample before a shallow trench isolation (STI) etchback.

FIG. 4 is a diagram illustrating an exemplary cross-sectional shape of the sample when a plasma processing method according to a third embodiment of the invention is applied to the STI etchback using the plasma processing apparatus of FIG. 1.

FIG. 5 is a diagram illustrating an exemplary cross-sectional shape of the sample when the STI etchback is performed using an apparatus of the related art.

FIG. 6 is a diagram illustrating an exemplary cross-sectional shape of the sample after the STI etchback is performed using another apparatus of the related art.

FIG. 7 is a cross-sectional view for describing magnetic flux lines in the ECR plasma processing apparatus of FIG. 1.

FIG. 8 is a plan view illustrating exemplary arrangement of holes in a perforated plate of the ECR plasma processing apparatus of FIG. 1.

FIG. 9 is a plan view illustrating another exemplary arrangement of holes in the perforated plate of the ECR plasma processing apparatus of FIG. 1.

FIG. 10A is a diagram for describing an effect of existence/absence of the shielding plate in a fluorocarbon distribution to a distribution of film thickness of deposited fluorocarbon radical in the ECR plasma processing apparatus of FIG. 17 to illustrate a relationship of a deposition rate of film thickness against a radial position on sample.

FIG. 10B is a diagram for describing a fluorocarbon distribution in a distribution of film thickness of deposited fluorocarbon radical in the ECR plasma processing apparatus of FIG. 18 to illustrate a relationship of a deposition rate of film thickness against the radial position on sample.

FIG. 11 is an apparatus cross-sectional view illustrating a part of a manufacturing process of a NAND flash memory having a three-dimensional structure, in which FIG. 11 (a) illustrates a state in which a stacked film is fabricated including a silicon nitride film and a silicon oxide film, FIG. 11 (b) illustrates a state in which the silicon nitride film is removed, and the silicon oxide film having a comb tooth shape is formed, FIG. 11(c) illustrates a state in which a tungsten film is formed by covering the silicon oxide film having the comb tooth shape, and FIG. 11(d) illustrates a state in which the tungsten film is removed while the tungsten film remains in gaps of the silicon film of the comb tooth shape.

FIG. 12 is a cross-sectional view illustrating an exemplary fabrication shape subjected to a tungsten removal process through isotropic etching for the structure of FIG. 11(c).

FIG. 13 is a cross-sectional view illustrating an exemplary fabrication shape subjected to a tungsten removal process through isotropic etching after a tungsten removal process for a bottom of trench for the structure of FIG. 11 (c).

FIG. 14 is a diagram for describing a radical concentration distribution inside the trench during the processing to illustrate a relationship of an F-radical concentration against a distance from the bottom surface of trench in the structure of FIG. 12.

FIG. 15 is a diagram for describing a radical concentration distribution inside the trench during the processing to illustrate a relationship of the F-radical concentration against the distance from the bottom surface of trench in the structure of FIG. 11(c).

FIG. 16 illustrates a shape of the shielding plate according to a fifth embodiment of the invention.

FIG. 17 is a schematic cross-sectional view illustrating a whole configuration of a plasma processing apparatus according to the fifth embodiment of the invention.

FIG. 18 is a schematic cross-sectional view illustrating a whole configuration of a plasma processing apparatus according to a sixth embodiment of the invention.

FIG. 19 is an enlarged view illustrating a perforated plate according to the sixth embodiment of the invention.

FIG. 20 is a flowchart illustrating a metal gate formation process according to a seventh embodiment of the invention.

### DESCRIPTION OF EMBODIMENTS

Embodiments of the invention will now be described.

### First Embodiment

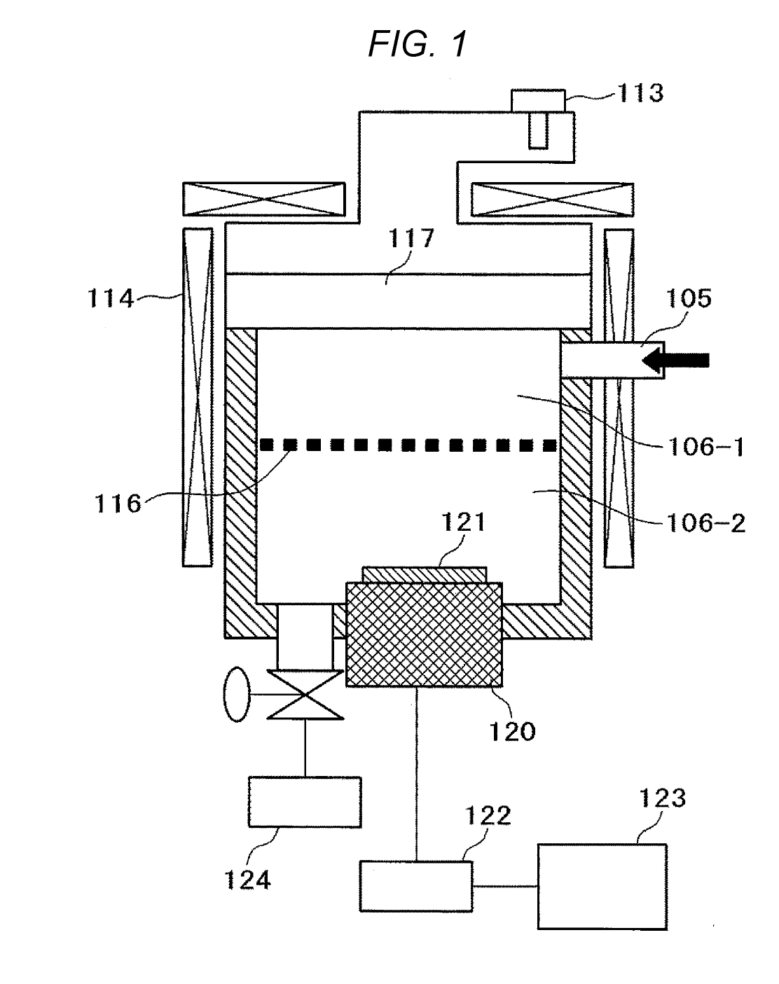

FIG. 1 is a schematic cross-sectional view illustrating a whole configuration of a plasma processing apparatus according to a first embodiment of the invention. Similarly to the technique of PTL 2, the apparatus according to this embodiment has a structure capable of generating plasma by virtue of an electron cyclotron resonance (ECR) phenomenon between 2.45 GHz microwaves supplied from a magnetron 113 to a vacuum processing chamber 106 (upper area 106-1 and lower area 106-2) through a dielectric window 117 and magnetic fields generated by the solenoidal coil 114. In addition, similarly to the technique of PTL 2, a radio frequency power source 123 is connected to a sample 121 placed on a sample stage 120 by interposing an impedance matcher 122.

This plasma processing apparatus is different from that of PTL 2 in that a perforated plate 116 formed of a dielectric material partitions the inside of the vacuum processing chamber 106 into a vacuum processing chamber upper area 106-1 and a vacuum processing chamber lower area 106-2. Due to this feature, if plasma can be generated from the vacuum processing chamber upper area 106-1 in the dielectric window side of the perforated plate 116 serving as a shielding plate, it is possible to shield ions and irradiate only radicals onto the sample. The ECR plasma processing apparatus used in this embodiment is different from the microwave plasma processing apparatus discussed in PTL 4 in that plasma is generated in the vicinity of a surface having a magnetic field intensity of 875 Gauss called an ECR surface.

For this reason, if the magnetic field is controlled such that the ECR surface is located between the perforated plate 116 and the dielectric window 117 (vacuum processing chamber upper area 106-1), plasma can be generated in the dielectric window side of the perforated plate 116. In addition, since nearly all of the generated ions are prevented from passing through the perforated plate 116, it is possible to irradiate only radicals onto the sample 121. Furthermore, according to this embodiment, unlike the apparatus of PTL 3, the perforated plate 116 is formed of a dielectric material. Since the perforated plate 116 is not formed of metal, microwaves can propagate to the sample side from the perforated plate 116.

Therefore, if the magnetic field is controlled such that the ECR surface is located between the perforated plate 116 and the sample 121 (vacuum processing chamber lower area 106-2), plasma is generated in the sample side from the perforated plate 116. Therefore, it is possible to irradiate both ions and radicals onto the sample. In addition, unlike the capacitively coupled plasma of PTL 1, using this method, it is possible to control the ion irradiation energy between several tens eV to several KeV by controlling the power supplied to the sample stage from the radio frequency power source 123. Note that adjustment or switching (upward or downward) of a height position of the ECR surface with respect to the height position of the perforated plate, a time for holding each height position, or the like may be performed using a controller (not illustrated). An element 124 is a pump.

In order to maintain plasma in this method, a width of the space where the plasma is generated necessarily has a sufficient size to maintain the plasma. As a result of examination for the generation of plasma by experimentally changing a distance between the perforated plate 116 and the dielectric window 117 and a distance between the perforated plate 116 and the sample 121, it was found that stable plasma can be generated if this gap is set to 40 mm or longer.

In plasma processing apparatuses such as a dry-etching apparatus for generating plasma on the basis of a magnetic field and a microwave ECR phenomenon, a radical irradiation step and an ion irradiation step can be implemented using a single apparatus by placing a dielectric perforated plate between the sample and the dielectric window and vertically moving the position of the ECR surface. Furthermore, by adjusting power supplied to the sample stage of the radio frequency power source, it is possible to control the ion irradiation energy from several tens eV to several KeV.

As a result, it is possible to evenly etching a sample having both a wide etching area and a narrow etching area to a desired depth using a single apparatus while suppressing a micro-loading effect. As a material of the dielectric perforated plate, a material having a low dielectric loss such as quartz, alumina, or yttria is preferably employed.

### Second Embodiment

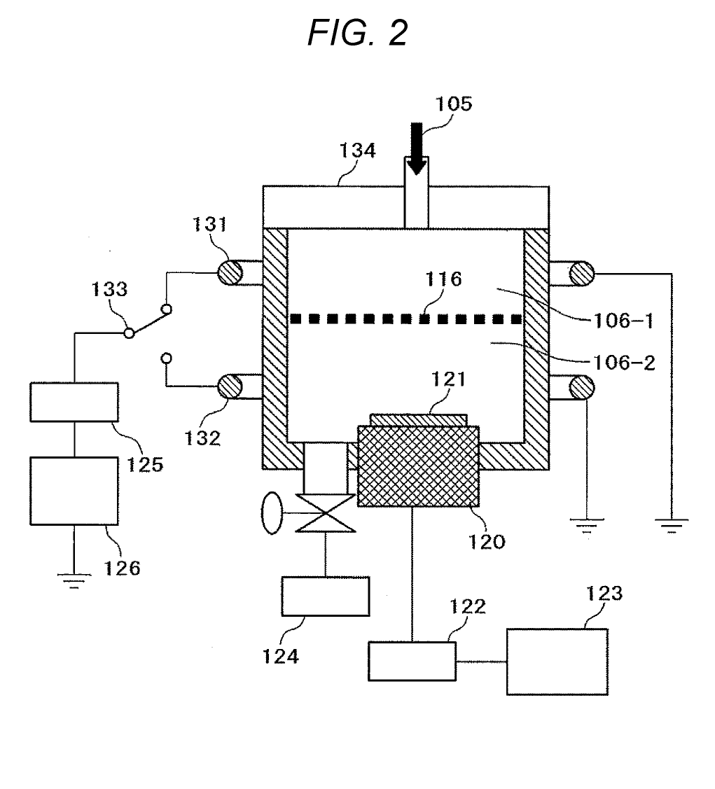

FIG. 2 is a schematic cross-sectional view illustrating a whole configuration of the plasma processing apparatus according to a second embodiment of the invention. Similarly to the technique of PTL 1, this apparatus can generate inductively coupled plasma by supplying radio frequency power from the radio frequency power source 126 to the helical coil 131 through the impedance matcher 125. In addition, similarly to the technique of PTL 1, a grounded perforated plate 116 formed of metal is inserted between this inductively coupled plasma and the sample, and the radio frequency power source 123 is connected to the sample 121 placed on the sample stage 120 through the impedance matcher 122. Note that the perforated plate 116 may be formed of any conductor without limiting to the metal.

Meanwhile, this apparatus is different from that of PTL 1 in that another helical coil 132 is provided in a height between the metal perforated plate 116 and the sample 121 in order to generate inductively coupled plasma even in the sample side relative to the metal perforated plate 116 (in the vacuum processing chamber lower area 106-2). Which one of the helical coils 131 and 132 the radio frequency power is supplied to can change over by the switch 133. In a case where the radio frequency power is supplied to the helical coil 131, plasma is generated in a top plate side of the perforated plate 116 (vacuum processing chamber upper area 106-1). Therefore, ions are shielded by the perforated plate 116, and only radicals are irradiated onto the sample 121.

In a case where the radio frequency power is supplied to the helical coil 132, plasma is generated in the sample side relative to the perforated plate 116 (vacuum processing chamber lower area 106-2). Therefore, it is possible to irradiate ions onto the sample 121. Note that a controller (not illustrated) may be used to perform a changeover of the helical coil using the switch 133 (between the upper helical coil and the lower helical coil with respect to the perforated plate), each period until the changeover, and the like.

In this method, inductively coupled plasma can be generated in the sample side relative to the perforated plate 116. Therefore, by adjusting the power supplied from the radio frequency power source 123, it is possible to control the ion irradiation energy from several tens eV to several KeV. This method is different from that of PTL 1 in that irradiation can be controlled from low energy to high energy.

Even in this method, it is possible to generate stable plasma by setting the distance between the perforated plate 116 and the top plate 134 and the distance between the perforated plate 116 and the sample 121 to be at least one digit longer than the Debye length, for example, 5 mm or longer.

As described above, in the dry-etching apparatus in which inductively coupled plasma is generated by supplying radio frequency power to the helical coil, the metal perforated plate 116 is placed between the sample 121 and the top plate 134, and separate helical coils 131 and 132 are provided in the top plate side of the metal perforated plate 116 (vacuum processing chamber upper area 106-1) and the sample side of the metal perforated plate 116 (vacuum processing chamber lower area 106-2). Meanwhile, if a changeover mechanism for changing over the radio frequency power supplied to the two helical coils is provided, it is possible to implement a radical irradiation step and an ion irradiation step using a single apparatus. Furthermore, by adjusting the power of the radio frequency power source supplied to the sample stage, it is possible to control the ion irradiation energy from several tens eV to several KeV.

As a result, even in a sample where a wide etching area and a narrow etching area are mixedly provided, it is possible to perform etching evenly to a desired depth using a single apparatus while suppressing a micro-loading effect. The metal perforated plate 116 is preferably formed of a material having high conductivity such as aluminum, copper, and stainless steel. In addition, the metal perforated plate may be coated with a dielectric material such as alumina.

### Third Embodiment

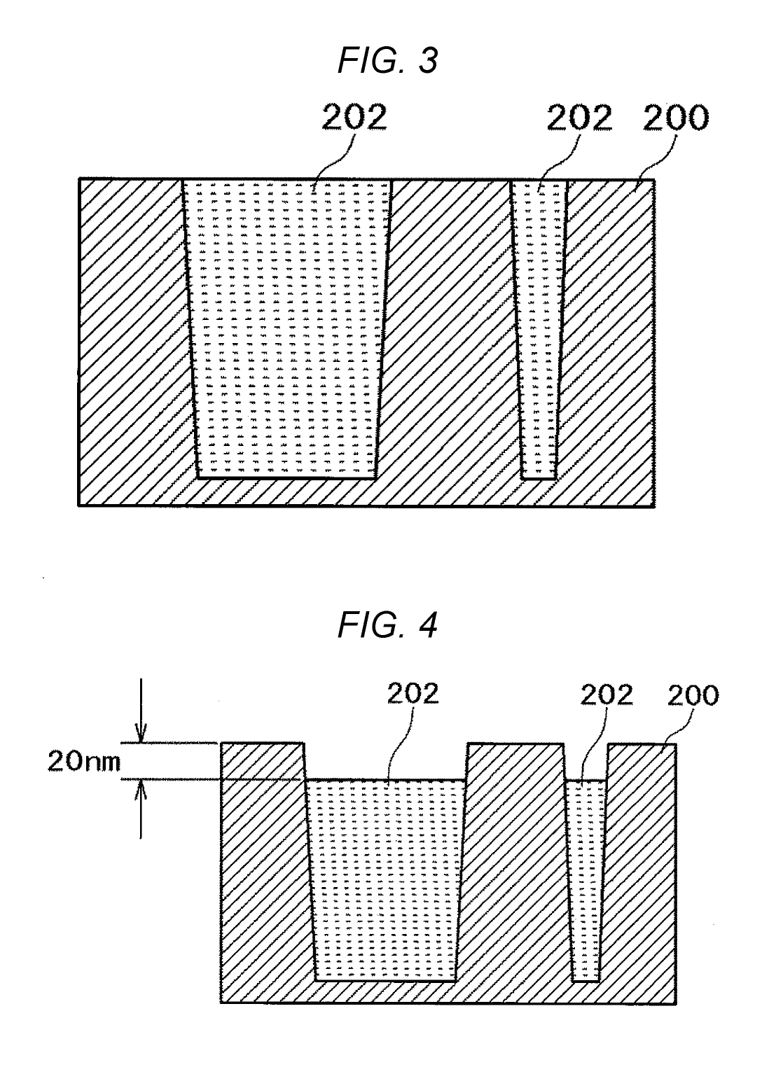

A plasma processing method according to a third embodiment of the invention will be described by exemplifying an etchback process of shallow trench isolation (STI) using the plasma processing apparatus described in the first embodiment. In this process, for example, as illustrated in FIG. 3, a sample is fabricated to have a structure in which the silicon oxide film (SiO₂) 202 is buried in the trench of the silicon (Si) 200 having a depth of 200 nm, and only the SiO₂ 202 is etched by 20 nm. For this fabrication, atomic layer etching was applied by alternately performing radical irradiation with fluorocarbon gas (first step) and ion irradiation with noble gas (second step).

In the first step, plasma is generated under a magnetic field condition that the ECR surface enters between the perforated plate 116 and the dielectric window 117 (vacuum processing chamber upper area 106-1) while a fluorocarbon gas is supplied from the gas inlet port 105. In addition, only radicals of the fluorocarbon gas are adsorbed on the sample by removing ions with the perforated plate 116. In this case, the radio frequency power from the radio frequency power source 123 is not applied to the sample.

Then, in the second step, plasma is generated under a magnetic field condition that the ECR surface enters between the perforated plate 116 and the sample (vacuum processing chamber lower area 106-2) while a noble gas is supplied from the gas inlet port 105. In addition, only ions having energy of 30 eV are irradiated onto the sample by applying radio frequency power of 30 W to the sample, so that SiO₂ is selectively etched against Si. Note that the energy of ions can be controlled by adjusting the radio frequency power supplied to the sample.

Etching of 20 nm can be performed by alternately repeating the first and second steps fifty times. FIG. 4 illustrates a cross-sectional shape of the sample fabricated in this method. It is recognized that SiO₂ 202 buried in the trench of Si 200 is etched accurately by 20 nm.

For comparison, atomic layer etching was performed similarly using the apparatus described in PTL 1. Specifically, in the first step, inductively coupled plasma is generated by supplying radio frequency power to the helical coil while supplying a fluorocarbon gas from the gas inlet port. In addition, the radio frequency voltage is not applied to the sample. As a result, only radicals of the fluorocarbon gas are irradiated from the inductively coupled plasma onto the sample. In addition, in the second step, capacitively coupled plasma is generated between the metal perforated plate and the sample by applying radio frequency power of 1 kW onto the sample while supplying a noble gas from the gas inlet port, and ions of the noble gas are irradiated onto the sample.

FIG. 5 illustrates a cross-sectional shape obtained by fabricating the sample after alternately repeating the first and second steps fifty times. It is recognized that the SiO₂ 202 buried in the trench of Si 200 is etched accurately by 20 nm. Meanwhile, it is recognized that selectivity is low because the Si 200 is also etched nearly by 20 nm. That is, ions are accelerated by the radio frequency power of 1 kW applied to the sample to generate the capacitively coupled plasma, and the Si is also etched. If the radio frequency power applied to the sample decreases, the capacitively coupled plasma is not generated. Therefore, it is difficult to control the ion acceleration energy.

In addition, atomic layer etching was similarly performed using the apparatus described in PTL 2. Specifically, in the first step, a fluorocarbon gas was supplied from the gas inlet port while generating ECR plasma. In addition, a radio frequency voltage was not applied to the sample. As a result, radicals and ions of the fluorocarbon gas are irradiated from the inductively coupled plasma to the sample. Furthermore, in the second step, a noble gas was supplied from the gas inlet port while generating ECR plasma. Moreover, only ions having energy of 30 eV are irradiated onto the sample by applying radio frequency power of 30 W onto the sample, so that the SiO₂ 202 is selectively etched against the Si 200.

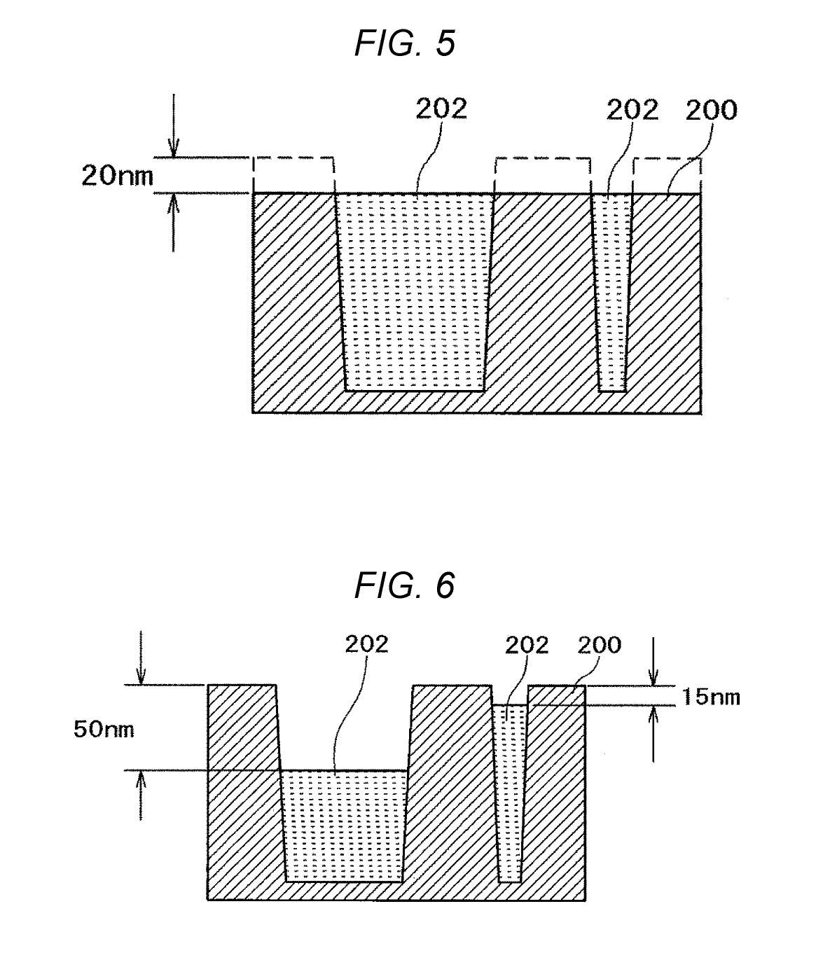

FIG. 6 illustrates a cross-sectional shape of the sample fabricated by alternately repeating the first and second steps fifty times. In the wide width area of the trench of the Si 200, it is recognized that the buried SiO₂ 202 is etched by approximately 50 nm, and the etching depth control accuracy is low. Meanwhile, in the narrow width area of the trench of the Si 200, it is recognized that the SiO₂ 202 is etched merely by approximately 15 nm, and an iso-dense bias is large (micro-loading effect).

As described above, it is possible to implement both the steps using the same apparatus without conveying the sample by alternately repeating irradiation with the fluorocarbon gas radicals and irradiation with the noble gas ions using the apparatus according to the first embodiment. Therefore, it is possible to implement the STI etchback with high selectivity, high accuracy, and high throughput. In addition, it is possible to control the ion irradiation energy from several tens eV to several KeV by adjusting the power supplied to the sample stage from the radio frequency power source. As a result, even a sample in which a wide etching area and a narrow etching area are mixedly provided can be evenly etched to a desired depth using a single apparatus by suppressing a micro-loading effect. The fluorocarbon gas according to this embodiment may include C₄F₈, C₂F₆, C₅F₈, and the like. In addition, the noble gas may include He, Ar, Kr, Xe, and the like.

### Fourth Embodiment

In this embodiment, influence on the ion shielding performance caused by arrangement of the holes on the perforated plate of the apparatus of the first embodiment will be described.

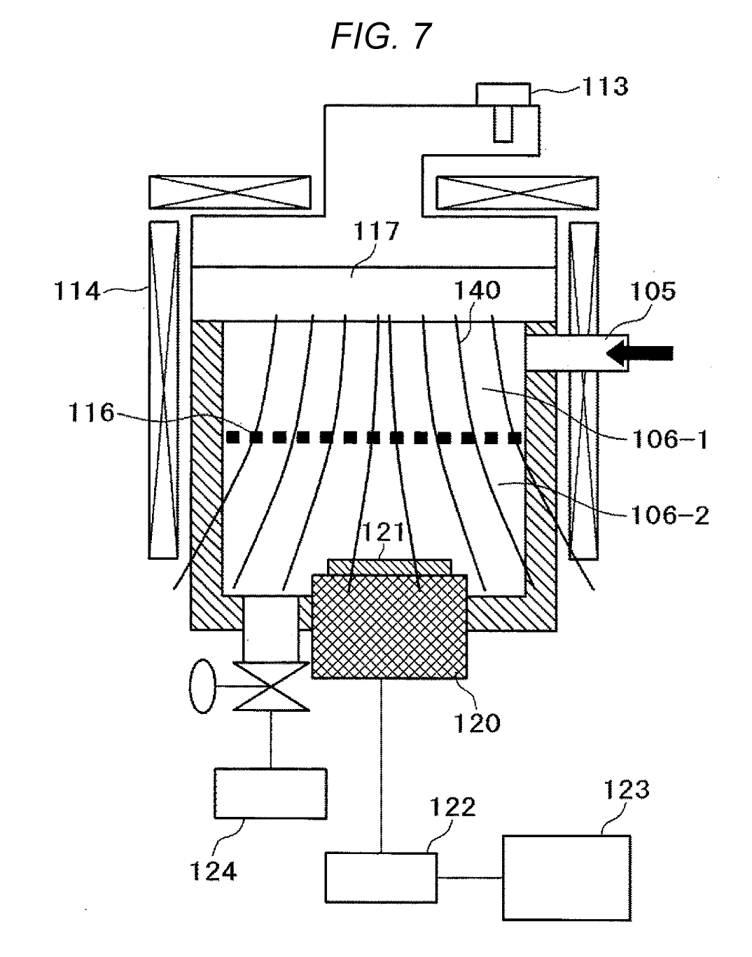

First, an ion shielding effect will be described. It is known that, in the plasma applied with a magnetic field, ions move along a magnetic flux lines. FIG. 7 is an apparatus cross-sectional view for describing a state of the magnetic flux line 140 in the plasma processing apparatus of FIG. 1. In the case of the ECR plasma, as illustrated in FIG. 7, the magnetic flux lines 140 run vertically, and interval between the magnetic flux lines are widened as closer to the sample.

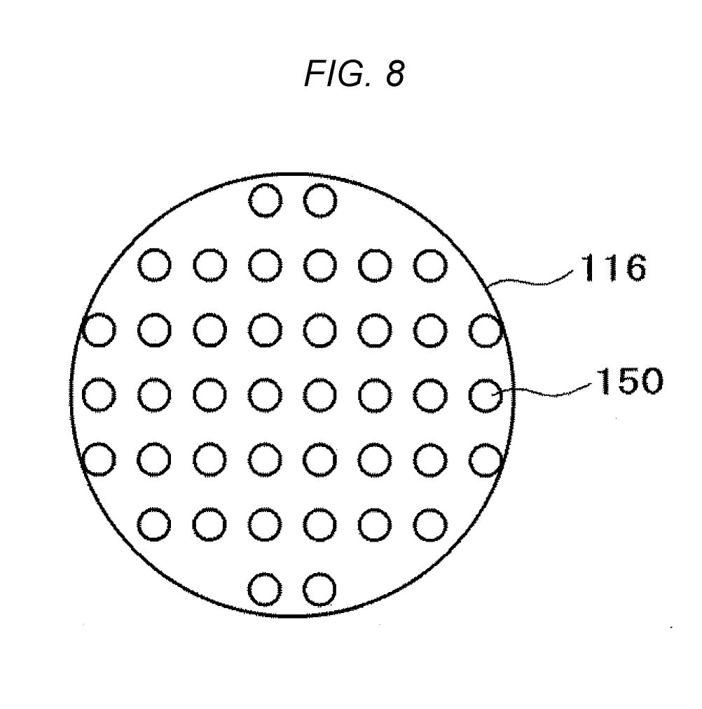

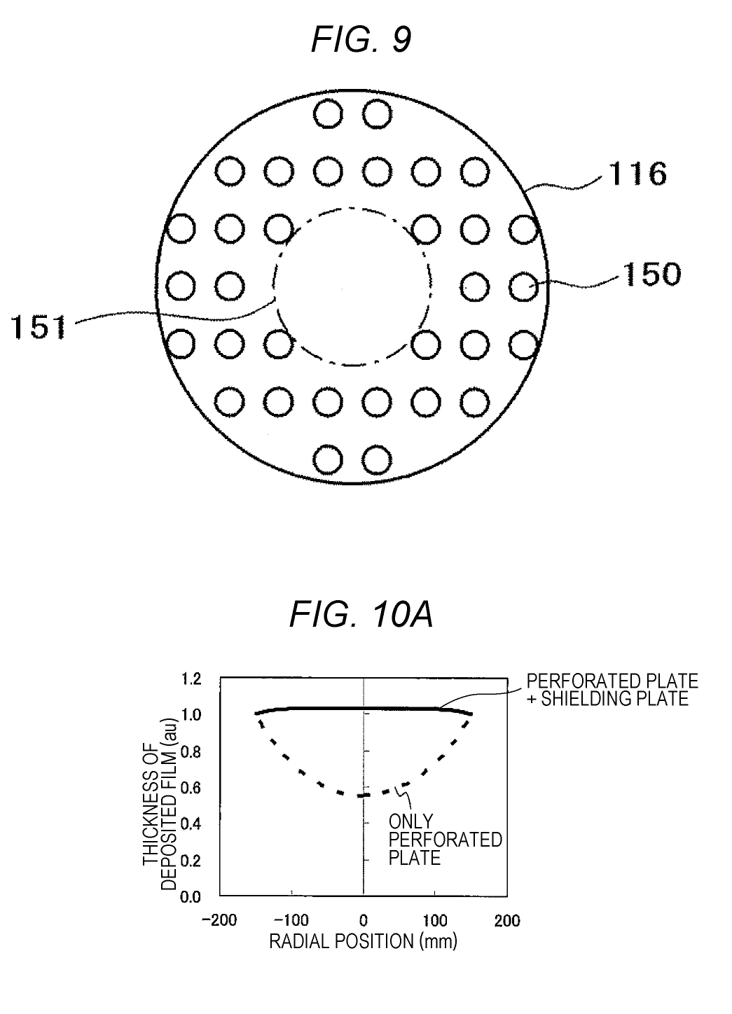

Therefore, in the case of the perforated plate 116 having holes 150 uniformly arranged as illustrated in FIG. 8, the ions passing through the vicinity of the center are incident to the sample 121 along the magnetic flux lines 140. Meanwhile, if holes are not provided in a range 151 (radical shielding area) corresponding to the diameter of the sample in the center of the perforated plate 116 as illustrated in FIG. 9, it is possible perfectly shield ions generated in the dielectric window side (vacuum processing chamber upper area 106-1) of the perforated plate and incident to the sample. Note that the diameter of the hole 150 is preferably set to 1 to 2 cmφ.

In order to verify this effect, an ion current density incident to the sample was measured by generating plasma of a noble gas under a magnetic field condition in which the ECR surface enters between the perforated plate 116 and the dielectric window for three cases, for a case of no perforated plate, for a case that the perforated plate of FIG. 8 is installed, and for a case that the perforated plate of FIG. 9 is installed. As a result, in the case of no perforated plate, the ion current density was 2 mA/cm². In comparison, in the case of the perforated plate of FIG. 8, the ion current density was 0.5 mA/cm². In the case of the perforated plate of FIG. 9, the ion current density was reduced to 0.02 mA/cm² or smaller, which is a measurement limitation. That is, it was recognized that, using the perforated plate having a structure provided with no hole in the range 151 of the center corresponding to the diameter of the sample, it is possible to remarkably reduce ions incident to the sample.

### Fifth Embodiment

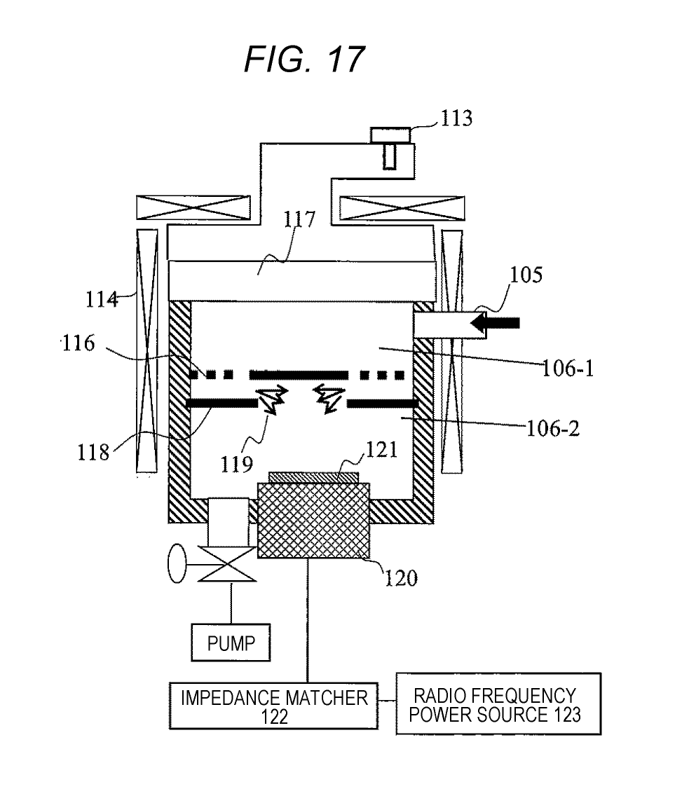

In this embodiment, influence on a radical distribution caused by the perforated plate of the apparatus of the first embodiment will be described. In a case where the perforated plate having no hole in the vicinity of the center as illustrated in FIG. 9 is employed, radicals are supplied from the holes of the outer periphery of the perforated plate, the radical distribution in the vicinity of the sample tends to be high in the outer periphery. In order to address this problem, a method of installing a doughnut-shaped second shielding plate 118 having an opening in the center as illustrated in FIG. 16 in the sample side of the perforated plate of FIG. 9 was studied. As a result, as illustrated in the cross-sectional view of FIG. 17, a gas flow 119 directed from a gap between the perforated plate 116 and the second shielding plate 118 to the center is generated, so that radicals are also supplied to the vicinity of the center of the sample.

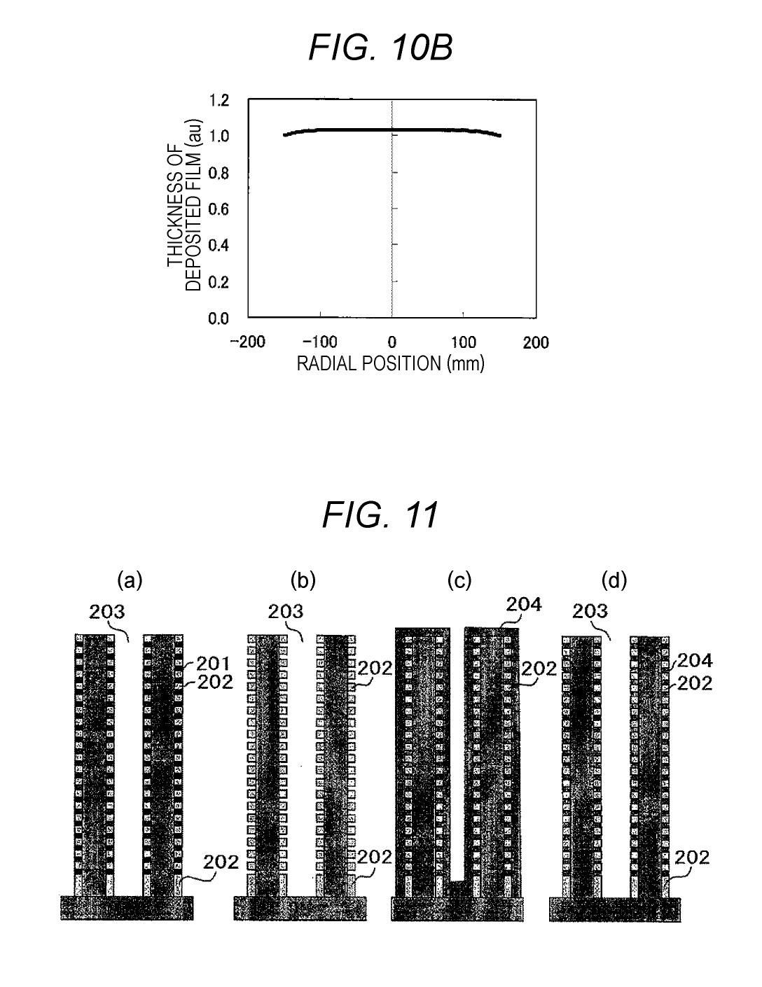

In order to verify this effect, for a case where only the perforated plate of FIG. 9 is provided and for a case where the perforated plate of FIG. 9 and the second shielding plate of FIG. 16 are combined, a distribution of the thickness of the deposited film on the sample caused by fluorocarbon radicals was measured by generating fluorocarbon gas plasma under a magnetic field condition in which the ECR surface enters between the perforated plate 116 and the dielectric window 117. The result is illustrated in FIG. 10A. In the case of only the perforated plate of FIG. 9, the outer side was higher in the thickness distribution. However, in the case of a combination of the perforated plate of FIG. 9 and the second shielding plate of FIG. 16, it was possible to obtain a uniform thickness distribution. That is, it was recognized that a uniform radical distribution can be obtained by combining the perforated plate of FIG. 9 and the second shielding plate of FIG. 16.

Although a perforated plate having no holes in the range corresponding to the sample diameter in the center is employed in this embodiment, the same effect can be obtained by using a perforated plate obtained by reducing a density of the holes or a hole diameter in this area. In addition, a diameter of the area having few holes can be reduced by approximately 30% from the diameter of the sample although it depends on a distance between the perforated plate and the sample or the magnetic field condition.

In order to obtain this effect, it is necessary to set the diameter of the opening of the second shielding plate to be smaller than the diameter of the area having no hole of the perforated plate. The second shielding plate may be formed of a dielectric material such as quartz or alumina or a metal material. In addition, the second shielding plate may not be a plate, but may have, for example, a block shape having an opening in the center.

### Sixth Embodiment

In this embodiment, a method of obtaining both the ion shielding performance and the uniform radical distribution by improving a method of forming holes on the perforated plate of the apparatus of the first embodiment was studied. In order to supply radicals to the center, it is necessary to form holes in the vicinity of the center as in the perforated plate of FIG. 8. Meanwhile, since ions move along the magnetic flux lines 140, the ions passing through the holes in the vicinity of the center are incident to the sample 121.

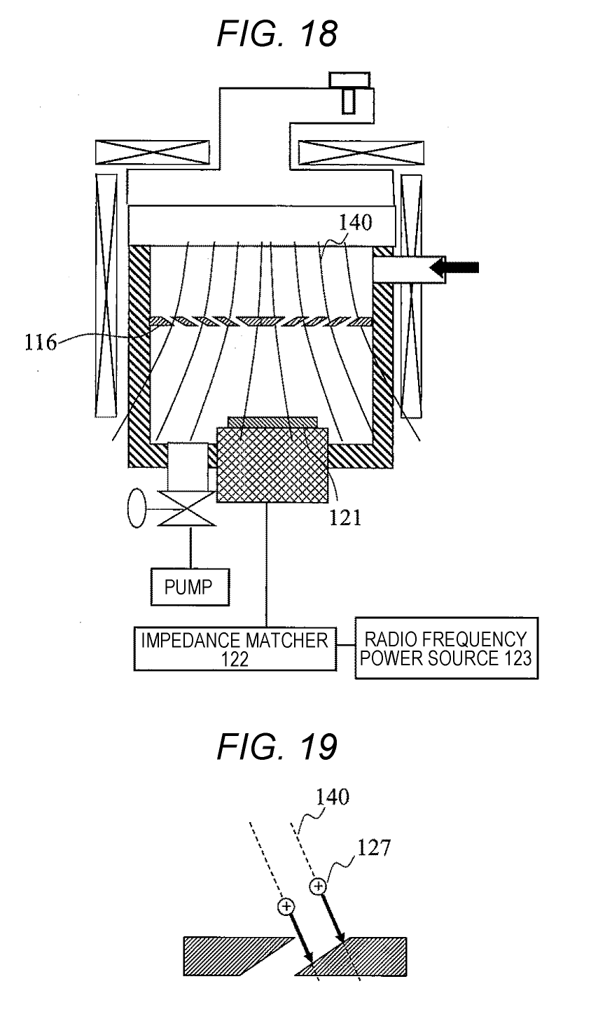

In this regard, the inventors studied a method of forming sloped holes in the perforated plate as illustrated in the cross-sectional view of FIG. 18. As illustrated in FIG. 18, in the microwave ECR plasma, the magnetic flux lines are inclined such that intervals of the magnetic flux lines 140 are widened as closer to the sample. In the apparatus of FIG. 18, the opening is sloped reversely to the inclinations of the magnetic flux lines. That is, it is characterized that the holes are sloped so as to narrow the intervals of the holes in the sample side.

In this case, as illustrated in the enlarged view of FIG. 19, directions of holes are different from the directions of the magnetic flux lines 140. Therefore, ions 127 fail to pass through the holes of the perforated plate, and as a result, it is possible to remarkably reduce the amount of ions incident to the sample 121. Meanwhile, since radicals can be isotropically dispersed regardless of the magnetic flux line, they can reach the sample through the sloped holes of the perforated plate. Therefore, it is possible to supply radicals from the holes of the vicinity of the center. In order to verify this effect, an ion current density on the sample was measured using the configuration of FIG. 18. As a result, the ion current density was reduced from 0.5 mA/cm² for the case of the perforated plate having vertical holes to 0.02 mA/cm² or smaller, which is a measurement limitation.

Then, a distribution of the deposited film on the sample was measured using the method of the fifth embodiment. The result is illustrated in FIG. 10B. It was possible to obtain a uniform thickness distribution by forming holes in the vicinity of the center. That is, it was recognized that it is possible to obtain both a high ion shielding performance and a uniform radical distribution by forming sloped holes in the vicinity of the center of the perforated plate.

It is preferable that the angle of the sloped hole of the perforated plate be set such that the entrance of the hole is not seen from the exit as seen from a perpendicular direction of the perforated plate. In addition, the holes may be sloped in a rotational direction instead of the center axis direction. Furthermore, although the sloped holes are formed in the entire perforated plate in this embodiment, the same effect can also be obtained by perpendicularly forming the holes in an area outward of the diameter of the sample.

### Seventh Embodiment

In this embodiment, a case where the apparatus of the first embodiment is applied to a part of a manufacturing process of a three-dimensional NAND (3D-NAND) well known in the art will be described. FIG. 11(a) illustrates a state of a trench 203 when a plurality of holes are formed in a stacked film obtained by alternately stacking the silicon nitride film 201 and the silicon oxide film 202, the holes are filled, and then, the trench 203 is formed. A silicon oxide film 202 having a comb tooth shape is formed as illustrated in FIG. 11 (b) by removing the silicon nitride film 201 from the sample having such a structure.

Tungsten 204 is formed through a chemical vapor deposition (CVD) method to bury gaps of the silicon oxide film 202 having the comb tooth shape and cover the silicon oxide film, so that a structure of FIG. 11(c) is obtained. In addition, by etching the tungsten 204 in a horizontal direction, a structure is formed as illustrated in FIG. 11(d) such that the silicon oxide film 202 and the tungsten 204 are alternately stacked, and each layer of the tungsten 204 is electrically separated. In the process of forming the structure of FIG. 11(d), it is necessary to evenly etch the tungsten 204 inside the deep trench in a horizontal direction.

As a method of evenly etching the tungsten 204 buried in the deep trench in a horizontal direction, for example, plasma processing using a gas mixture containing a fluorine-containing gas capable of isotropically etching the tungsten and a deposition gas such as fluorocarbon is conceived.

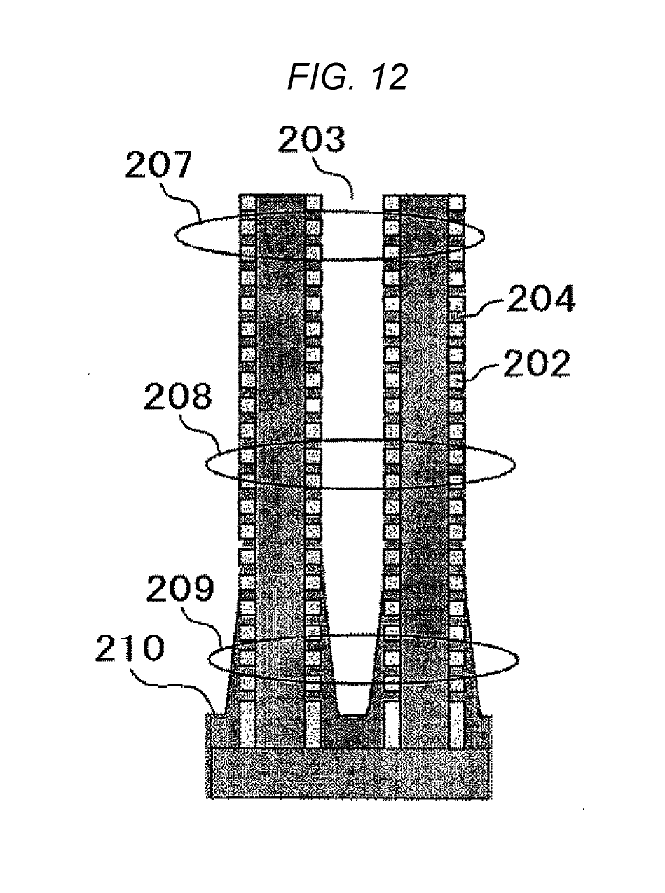

In this regard, using the apparatus of the first embodiment, the sample having the structure of FIG. 11(c) was treated by generating plasma of a gas mixture of a fluorine-containing gas and fluorocarbon. In order to implement isotropic etching, plasma was generated under a magnetic field condition in which the ECR surface enters between the perforated plate 116 and the dielectric window, and only radicals of fluorine and a fluorocarbon gas are irradiated onto the sample. In this case, the sample was treated without applying the radio frequency power. The result is illustrated in FIG. 12. It was recognized that the tungsten 204 is evenly removed in the trench top portion 207 and the trench center portion 208, but the tungsten 204 remains without being etched in the bottom of trench 209, so that an electric short circuit is generated between each layer of the tungsten 204.

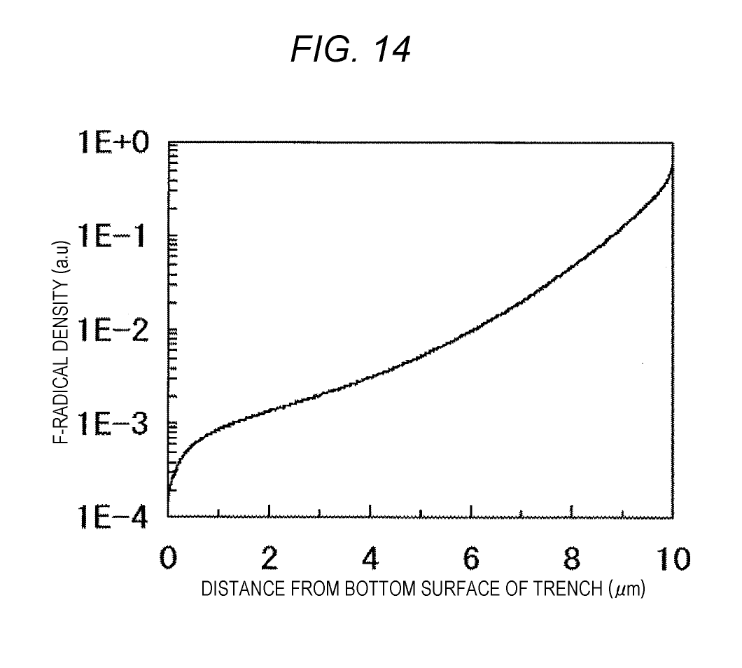

Next, a reason thereof will be described. FIG. 14 illustrates a relationship of the F-radical concentration against a distance from the bottom of trench (tungsten surface of bottom of trench). As recognized from FIG. 14, it is recognized that a concentration of fluorine radicals is abruptly reduced in the bottom of trench 209 (where the distance from the bottom of trench is around zero). It was estimated that a cause of this reduction is that the fluorine radicals are consumed through the etching of the tungsten surface of bottom of trench 210.

In order to address this problem, a two-step fabrication method was investigated, in which tungsten of the bottom of trench is removed through anisotropic etching, and then, the tungsten 204 of the side surface is removed isotropically. In the anisotropic etching step, the tungsten 204 of the bottom of trench was removed by generating plasma under a magnetic field condition in which the ECR surface enters between the perforated plate 116 and the sample 121 and applying radio frequency power to the sample to normally inject ions to the sample. Note that the ion irradiation energy can be controlled from several tens eV to several KeV by adjusting the power supplied to the sample stage from the radio frequency power source.

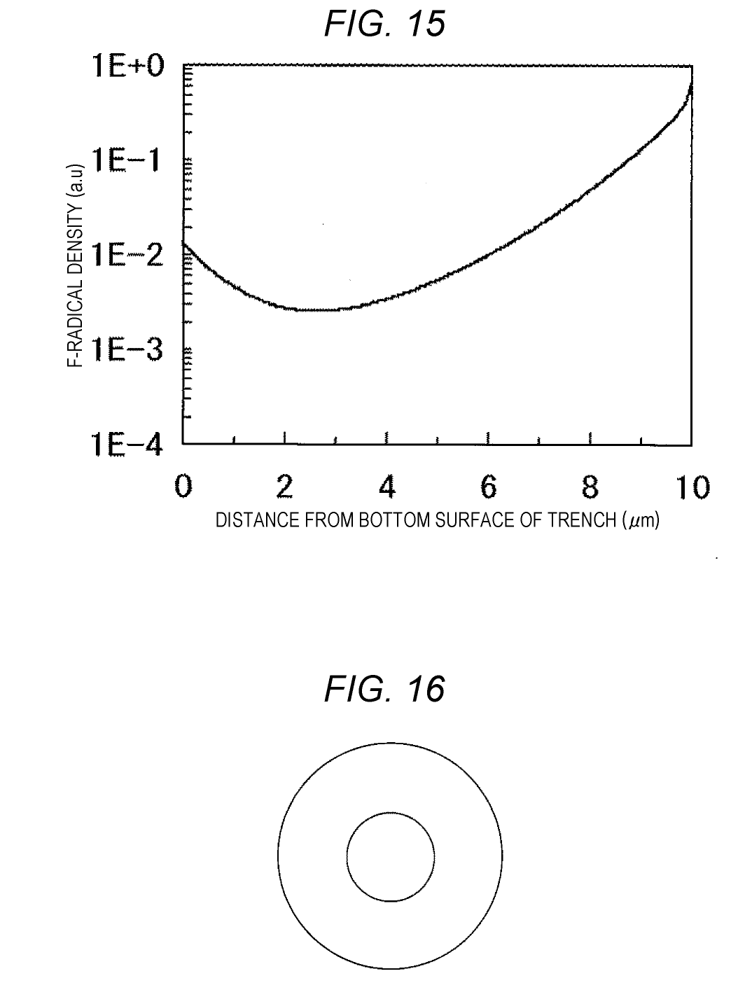

Then, in the isotropic etching, the processing was performed by generating plasma under a magnetic field condition in which the ECR surface enters between the perforated plate 116 and the dielectric window 117 and without applying a radio frequency bias to the sample. As a result, in the isotropic etching step, the concentration of fluorine radicals is not abruptly reduced in the vicinity of the bottom of trench 209 as illustrated in FIG. 15.

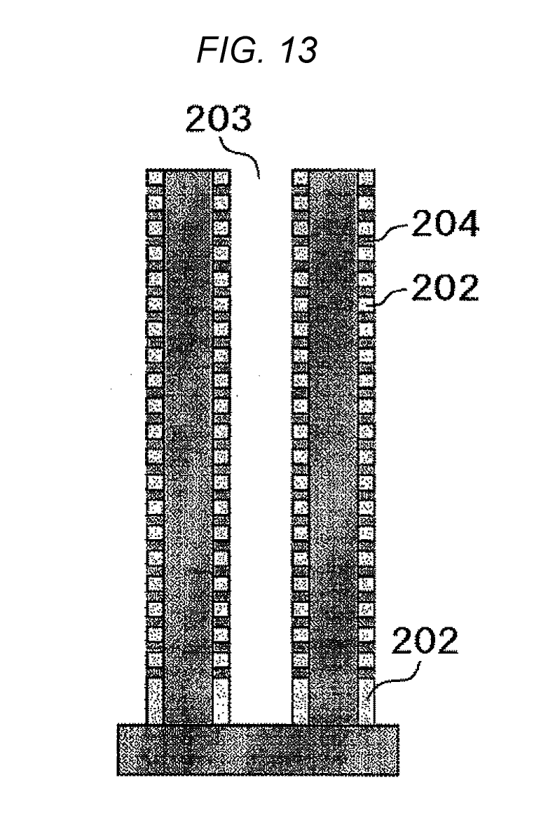

FIG. 13 illustrates a fabrication cross-sectional shape when this two-step processing is performed. In this method, it was recognized that the tungsten 204 is removed evenly to the bottom.

The fluorine-containing gas in this embodiment may include SF₆, NF₃, XeF₂, SiF₄, and the like. In addition, the fluorocarbon gas in this embodiment may include C₄F₈, C₂F₆, C₅F₈, and the like. Furthermore, although the trench 203 is employed in this embodiment, a hole may be employed instead.

Although the apparatus of the first embodiment is employed in this embodiment, the same effect can also be obtained by using the apparatus of the second embodiment as long as both the radical irradiation step and the ion radiation step can be implemented using a single apparatus.

### Eighth Embodiment

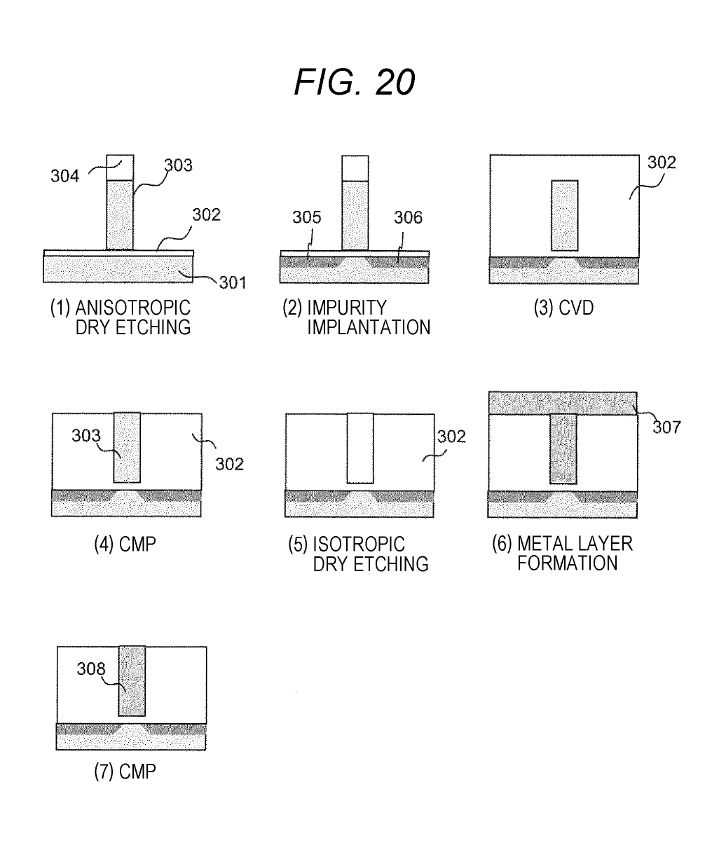

In this embodiment, an example of reducing the equipment cost by performing a plurality of processes using the apparatus of the first embodiment will be described. FIG. 20 illustrates a part of a metal gate formation process of a MOS transistor called a gate last process. First, in the first process, a silicon dummy gate 303 is formed by performing anisotropic dry etching for the silicon film formed on a silicon substrate 301 and a SiO2 302 along a mask 304.

Then, in the second process, a source 305 and a drain 306 are formed by implanting impurities. In the third process, the SiO₂302 is formed through chemical vapor deposition (CVD), and then, in the fourth process, the SiO2 302 on the remaining surface is polished through a chemical mechanical polishing (CMP). Then, in the fifth processing, the silicon dummy gate 303 is removed through isotropic dry etching of silicon. In addition, a metal 307 serving as a gate in practice is formed in the sixth process, and then, the remaining metal is removed through chemical mechanical polishing (CMP) in the seventh process, so that the metal gate 308 is provided.

In this process, there is an anisotropic silicon dry etching process in the first process, and there is an isotropic silicon dry etching process in the fourth process. Therefore, typically, one or more anisotropic silicon dry-etching apparatuses and one or more isotropic dry-etching apparatuses are necessary. For this reason, in fabrication laboratory producing a small quantity and wide variety of products, it is necessary to prepare two types of dry-etching apparatuses with a low operation time. This is disadvantageous in terms of the equipment cost.

If the anisotropic dry etching of the first process and the isotropic dry etching of the fourth process are performed using a single apparatus such as the apparatus of the first embodiment, it is possible to improve an equipment operation rate and reduce the number of the apparatuses in the fabrication laboratory to a half.

Although the apparatus of the first embodiment is applied to the MOS transistor metal gate formation process in this embodiment by way of example, the same effect can also be achieved in other manufacturing processes by treating both the anisotropic dry etching and the isotropic dry etching using the apparatus of the first embodiment as long as both the anisotropic dry etching and the isotropic dry etching exist.

### REFERENCE SIGNS LIST

105 gas inlet port
106-1 upper area of vacuum processing chamber 106
106-2 lower area of vacuum processing chamber 106
113 magnetron
114 coil
116 perforated plate
117 dielectric window
118 second shielding plate
119 gas flow
120 sample stage
121 sample
122 impedance matcher
123 radio frequency power source
124 pump
125 impedance matcher
126 radio frequency power source
127 ion
131 helical coil
132 helical coil
133 changeover switch
134 top plate
140 magnetic flux line
150 hole
151 center area having no hole (radical shielding area)
200 silicon
201 silicon nitride film
202 silicon oxide film
203 trench
204 tungsten
207 trench top portion
208 trench center portion
209 bottom of trench
210 tungsten surface of bottom of trench
301 substrate silicon
302 SiO2
303 dummy gate
304 mask
305 source
306 drain
307 metal
308 metal gate

1. A plasma processing apparatus comprising:
a processing chamber configured to perform plasma processing for a sample;
a radio frequency power source configured to supply radio frequency power for generating plasma in the processing chamber;
a sample stage where the sample is placed;
a shielding plate arranged over the sample stage to shield incidence of ions generated from the plasma into the sample stage; and
a controller configured to selectively perform one of controls for generating plasma over the shielding plate and the other control for generating plasma under the shielding plate.

2. The plasma processing apparatus according to claim 1, further comprising a magnetic field generating means configured to generate a magnetic field inside the processing chamber,
wherein the radio frequency power source supplies microwave radio frequency power to the inside of the processing chamber.

3. The plasma processing apparatus according to claim 1, further comprising:
a first induction coil for generating plasma over the shielding plate by an induced magnetic field; and
a second induction coil for generating plasma under the shielding plate by an induced magnetic field.

4. The plasma processing apparatus according to claim 2, wherein the shielding plate is formed of a dielectric material.

5. The plasma processing apparatus according to claim 3, wherein the shielding plate is formed of a conductor.

6. A plasma processing apparatus comprising:
a processing chamber configured to perform plasma processing for a sample;
a radio frequency power source configured to supply radio frequency power for generating plasma in the processing chamber;
a sample stage where the sample is placed;
a shielding plate arranged over the sample stage to shield incidence of ions generated from the plasma into the sample stage; and
a controller configured to control plasma processing by changing over between a first period for generating plasma over the shielding plate and a second period for generating plasma under the shielding plate.

7. The plasma processing apparatus according to claim 1, wherein the shielding plate includes a first shielding plate and a second shielding plate facing the first shielding plate, and
the second shielding plate does not have an opening in a portion facing an opening of the first shielding plate.

8. The plasma processing apparatus according to claim 1, further comprising a magnetic field generating means configured to generate a magnetic field inside the processing chamber,
wherein the shielding plate has a hole for supplying radicals to the sample stage, and
the hole has a slope against a vertical direction of the processing chamber directed oppositely to an inclination of the magnetic field against the vertical direction of the processing chamber.

9. A plasma processing method for performing plasma processing for a sample using a plasma processing apparatus including: a processing chamber configured to perform plasma processing for a sample; a radio frequency power source configured to supply radio frequency power for generating plasma in the processing chamber; a sample stage where the sample is placed; and a shielding plate arranged over the sample stage to shield incidence of ions generated from the plasma into the sample stage,
wherein one of controls for generating plasma over the shielding plate and the other control for generating plasma under the shielding plate are selectively performed.

10. The plasma processing method according to claim 9, wherein the plasma is microwave electron cyclotron resonance plasma, and
the plasma is generated over or under the shielding plate by controlling a magnetic flux density position for generating electron cyclotron resonance with the microwave.

11. A plasma processing method for performing plasma processing for a sample using a plasma processing apparatus including: a processing chamber configured to perform plasma processing for a sample; a radio frequency power source configured to supply radio frequency power for generating plasma in the processing chamber; a sample stage where the sample is placed; and a shielding plate arranged over the sample stage to shield incidence of ions generated from the plasma into the sample stage,
wherein plasma processing is performed by changing over between a first period for generating plasma over the shielding plate and a second period for generating plasma under the shielding plate.

12. The plasma processing method according to claim 11, wherein the plasma is microwave electron cyclotron resonance plasma, and
the plasma is generated over or under the shielding plate by controlling a magnetic flux density position for generating electron cyclotron resonance with the microwave.

13. A plasma processing method for removing a portion of a film buried in a pattern formed on a side wall of a hole or a trench other than the pattern by performing plasma etching, the method comprising:
removing the film perpendicularly to a depth direction of the hole or the trench after the film on the bottom surface of the hole or the trench is removed.

14. The plasma processing method according to claim 13, wherein the film of the hole or the bottom is removed through ion-assisted etching, and
the film is removed perpendicularly to the depth direction of the hole or the trench through radical etching.

15. The plasma processing apparatus according to claim 6, wherein the shielding plate includes a first shielding plate and a second shielding plate facing the first shielding plate, and
the second shielding plate does not have an opening in a portion facing an opening of the first shielding plate.

16. The plasma processing apparatus according to claim 6, further comprising a magnetic field generating means configured to generate a magnetic field inside the processing chamber,
wherein the shielding plate has a hole for supplying radicals to the sample stage, and the hole has a slope against a vertical direction of the processing chamber directed oppositely to an inclination of the magnetic field against the vertical direction of the processing chamber.
